(19) United States
(12) Patent Application Publication
(10) Pub. No.: US 2019/0096459 A1
(43) Pub. Date: Mar. 28, 2019

(54) MEMORY DEVICES FOR PERFORMING MULTIPLE WRITE OPERATIONS AND OPERATING METHODS THEREOF

(71) Applicant: Samsung Electronics Co., Ltd., Suwon-si (KR)

(72) Inventor: Jong-pil Son, Seongnam-si (KR)

(21) Appl. No.: 15/908,097

(22) Filed: Feb. 28, 2018

(30) Foreign Application Priority Data
Sep. 26, 2017 (KR) 10-2017-0124534

(51) Int. Cl. G11C 8/12; G11C 7/10; G06F 3/06

(52) U.S. Cl. CPC G11C 8/12; G11C 7/1096; G06F 3/0683; G06F 3/065; G06F 3/0659

(57) ABSTRACT

A memory device for performing a data write operation based on a multiple write command, an operating method thereof, and an operating method of a memory controller are provided. An operating method of a memory device including a plurality of banks includes receiving a write command, and data and an address corresponding to the write command, decoding the received write command, and responsive to a result of the decoding indicating that the write command corresponds to a multiple write command, together writing the same data in two or more banks using an internal address generating operation that is based on the received address.

### CROSS-REFERENCE TO RELATED APPLICATION

This U.S. nonprovisional patent application claims priority under 35 U.S.C. § 119 to Korean Patent Application No. 10-2017-0124534, filed on Sep. 26, 2017, in the Korean Intellectual Property Office, the entire contents of which are incorporated herein by reference.

### BACKGROUND

The inventive concepts relate to memory devices, and more particularly, to memory devices for performing a data write operation based on a multiple write command and operating methods thereof.

The capacity and speed of semiconductor memory devices used in high-performance electronic systems are increasing. As an example of on such semiconductor memory device, dynamic random access memory (DRAM) is a volatile memory that may read and/or write data based on an electric charge stored in a capacitor.

DRAM may include a memory cell array including a plurality of banks and may receive a write command and data corresponding thereto from a memory controller. The DRAM may be configured to store the data in the plurality of banks based on a result of decoding the write command. Enhancing a memory system may include improving the efficiency of the operations of the DRAM and/or the memory controller associated with the DRAM.

### SUMMARY

The inventive concepts provide memory devices, operating methods thereof, and operating methods of memory controllers which enhance a data write operation to improve the performance of a memory system.

According to an aspect of the inventive concepts, there is provided an operating method of a memory device including a plurality of banks, the operating method including receiving a write command and data and an address corresponding to the write command, decoding the write command, and responsive to a result of the decoding indicating that the write command corresponds to a multiple write command, together writing the same data in two or more banks using an internal address generating operation that is based on the received address.

According to another aspect of the inventive concepts, there is provided an operating method of a memory controller for controlling a memory device, the operating method including receiving an initialization request for the memory device from a host, generating a multiple write command to together write same initialization data in two or more banks of the memory device in response to the initialization request, transferring the multiple write command to the memory device, and transferring, to the memory device, a standard write command and an address indicating a position of a bank of the memory device in which data are to be written. Here, the multiple write command and the standard write command transferred to the memory device respectively include a plurality of fields. A first combination of the plurality of fields of the multiple write command is different than a second combination of the plurality of fields of the standard write command.

According to another aspect of the inventive concepts, there is provided a memory device including a memory cell array including a plurality of banks, a command decoder configured to decode a write command and an address received from a memory controller to control a write operation on the plurality of banks, and a bank controller block configured to select one or more of the plurality of banks in which data is to be written. Responsive to the command decoder decoding the write command as a standard write command, the data is written in one bank of the plurality of banks indicated by the address received from the memory controller. Responsive to the command decoder decoding the write command as a multiple write command, the data is together written in two or more banks of the plurality of banks of the memory cell array through an internal bank selecting operation

### BRIEF DESCRIPTION OF THE DRAWINGS

Embodiments of the inventive concepts will be more clearly understood from the following detailed description taken in conjunction with the accompanying drawings in which:

FIG. 1 is a block diagram illustrating a memory system according to an example embodiment of the inventive concepts;

FIG. 2 is a block diagram illustrating another example of a memory system according to an example embodiment of the inventive concepts;

FIG. 3 is a block diagram of a memory device illustrating an example of a multiple write operation;

FIGS. 4 and 5 are flowcharts illustrating an operating method of a memory device according to example embodiments of the inventive concepts;

FIGS. 6A and 6B are block diagrams illustrating an example where an embodiment of the inventive concepts is applied to a low power double data rate (LPDDR) or a high bandwidth memory (HBM);

FIG. 7 is a table showing an implementation example of a command/address signal for defining a multiple write command;

FIG. 8 is a table showing an example of selecting a plurality of banks on which multiple write is to be performed;

FIG. 9 is a block diagram illustrating an operation example where data is multiply written in a memory device according to an embodiment of the inventive concepts;

FIG. 10 is a table showing an example of don't care bits associated with at least one bit of a bank address;

FIGS. 11A, 11B, and 11C are block diagrams illustrating an example of a bank selecting operation based on the table of FIG. 10;

FIGS. 12 and 13 are diagrams illustrating an implementation example and an operating method of a memory system according to embodiments of the inventive concepts;

FIGS. 14 and 15 are diagrams illustrating an implementation example and an operating method of a memory device according to other embodiments of the inventive concepts;

FIG. 16 is a diagram illustrating an implementation example and an operating method of a memory system according to other embodiments of the inventive concepts; and

FIGS. 17A and 17B are diagrams illustrating an implementation example and an operating method of a memory device according to other embodiments of the inventive concepts.

### DETAILED DESCRIPTION

Hereinafter, embodiments will be described with reference to the accompanying drawings.

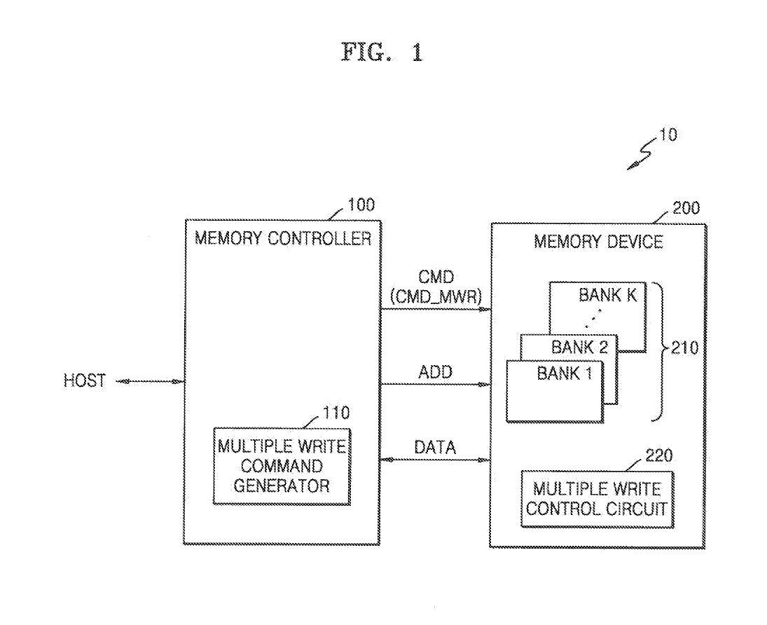

FIG. 1 is a block diagram illustrating a memory system 10 according to an example embodiment of the inventive concepts.

Referring to FIG. 1, the memory system 10 may include a memory controller 100 and a memory device 200. The memory controller 100 may provide various signals to the memory device 200 to control memory operations such as read and/or write. For example, the memory controller 100 may provide a command CMD and an address ADD to the memory device 200 to access data DATA of a memory cell array 210 of the memory device 200. The command CMD may include a command for standard memory operations such as reading and/or writing of data. Also, according to example embodiments of the inventive concepts, the command CMD may include a multiple write command CMD_MWR which issues a request, to the memory device 200, to perform a multiple write operation (e.g., repetitively write data to multiple memory locations). For example, the memory controller 100 may include a multiple write command generator 110, and the multiple write command generator 110 may generate the multiple write command CMD_MWR.

The memory controller 100 may access the memory device 200 according to a request from a host HOST. The memory controller 100 may communicate with the host HOST by using various protocols, and for example, the memory controller 100 may communicate with the host by using an interface protocol such as, for example, peripheral component interconnect-express (PCI-E), advanced technology attachment (ATA), serial ATA (SATA), parallel ATA (PATA), and/or serial attached SCSI (SAS). In addition, various interface protocols such as, for example, universal serial bus (USB), multi-media card (MMC), enhanced small disk interface (ESDI), and/or integrated drive electronics (IDE) may be applied to a protocol between the host HOST and the memory controller 100.

The memory device 200 may include the memory cell array 210 including a plurality of banks BANK 1 to BANK K and a multiple write control circuit 220. The memory device 200 may be, for example, dynamic random access memory (DRAM) such as double data rate synchronous dynamic random access memory (DDR SDRAM), low power double data rate (LPDDR) SDRAM, graphics double data rate (GDDR) SDRAM, or Rambus dynamic random access memory (RDRAM). However, the present embodiments are not limited thereto, and, for example, the memory device 200 may be implemented with a non-volatile memory such as flash memory, magnetic RAM (MRAM), ferroelectric RAM (FeRAM), phase change RAM (PRAM), and/or resistive RAM (ReRAM).

According to an embodiment, various kinds of commands may be defined between the memory controller 100 and the memory device 200, and commands which issue a request to perform standard memory operations such as write and/or read may be defined. As used herein, a “standard memory operation” may be a memory operation that does not use the multiple write data operation described herein. Also, according to an embodiment, a command for requesting a certain memory operation between the memory controller 100 and the memory device 200 may be defined. For example, the memory controller 100 may generate the multiple write command CMD_MWR which issues a request to write the same data DATA in a plurality of other regions of the memory cell array 210. For example, the memory controller 100 may generate the multiple write command CMD_MWR which issues a request to write the same data DATA in a plurality of banks together (e.g., simultaneously or non-simultaneously), and may provide the multiple write command CMD_MWR to the memory device 200. In some embodiments, being written together means that the data is written in each of the plurality of banks simultaneously. In some embodiments, being written together means that the same data is written in each of the each of the plurality of banks as a result of the single multiple write command, but the writing of the data in respective ones of the plurality of banks may be staggered (e.g., non-simultaneous). For example, a command may be implemented by a combination of a plurality of signals, and a combination of signals representing a standard write command in a data write operation may differ from a combination of signals representing the multiple write command CMD_MWR.

The multiple write control circuit 220 may perform a control operation for writing the same data DATA in the plurality of banks together in response to the multiple write command CMD_MWR. For example, the multiple write control circuit 220 may represent a set of various kinds of circuits which are necessary for writing the same data DATA in the plurality of banks together. For example, the multiple write control circuit 220 may include a decoding circuit (or a command decoder) for decoding the multiple write command CMD_MWR. Also, the multiple write control circuit 220 may further include an address generation circuit which generates an address for selecting two or more banks. Also, the multiple write control circuit 220 may further include a bank selection circuit (or a bank control circuit) for selecting two or more banks in which the same data DATA is to be written, based on the generated address.

In a standard write operation, the memory device 200 may write the data DATA in one bank that is indicated by an address ADD from the memory controller 100. In a multiple write operation, the memory device 200 may together write the data DATA in the one bank, that is indicated by the address ADD from the memory controller 100, and one or more banks which the memory device 200 additionally indicates. For example, when the multiple write command CMD_MWR is received, the multiple write control circuit 220 may generate an additional internal address from the received address ADD to perform a control operation for selecting two or more banks. However, the present embodiments are not limited thereto. In other embodiments, a certain bank selection pattern may be previously stored in the memory device 200, and two or more banks may be selected regardless of the address ADD of the one bank indicated by the memory controller 100.

According to the above-described example embodiment, in a case where the same data DATA is written in a plurality of banks, the memory device 200 may together (e.g., simultaneously or non-simultaneously) write the same data DATA in two or more banks, thereby reducing a time taken in a write operation. In some embodiments, the banks BANK 1 to BANK K of the memory device 200 may establish a configuration similar to a redundant array of independent disks (RAID) for enhancing data reliability. In such an embodiment, the same data DATA may be written in two or more of the banks BANK 1 to BANK K together. According to an embodiment, in implementing the RAID configuration for enhancing data reliability, the RAID may be implemented based on the multiple write operation provided by the multiple write command CMD_MWR.

Moreover, in an initialization operation of an electronic system to which the memory system 10 is applied, initialization data having a certain pattern may be written in the memory cell array 210, and in the initialization operation, the same data DATA may be written in the banks BANK 1 to BANK K. In this case, a multiple write operation according to an embodiment may be performed in the initialization operation, thereby reducing a time taken in writing the initialization data.

Moreover, according to the above-described embodiment, the amount of data and the number of commands transmitted/received between the host and the memory controller are reduced, and thus, bus capacity between the host and the memory controller is efficiently used. Also, the same data may be written in a plurality of banks, and thus, even in a case where one bank is used by another memory operation in a data read operation, the same data may be read from another bank, thereby enhancing data read performance.

The multiple write operation according to the above-described embodiment may be implemented in various ways. For example, whether to perform a multiple write operation may be determined by the host HOST. An electronic system to which the memory system 10 is applied may write certain data in the memory device 200 under certain conditions, and for example, an operation of outputting a graphic image including repetitive image data (e.g., a blue screen) may be performed under the certain conditions. In some embodiments, a need to write the same data DATA in two or more different regions may be determined by the host HOST for stability of data. In such an embodiment, the multiple write operation according to an embodiment of the inventive concepts may be performed by the memory controller 100 generating the multiple write command CMD_MWR, based on a request of the host HOST.

In some embodiments, the multiple write operation may be performed based on a determination by the memory controller 100. For example, the memory controller 100 may analyze data and an address which are internally queued (or stored) and may determine whether to write the same data in a plurality of banks of the memory cell array 210. In such an embodiment, the multiple write operation according to an embodiment of the inventive concepts may be performed by the memory controller 100 generating the multiple write command CMD_MWR, regardless of the request of the host HOST.

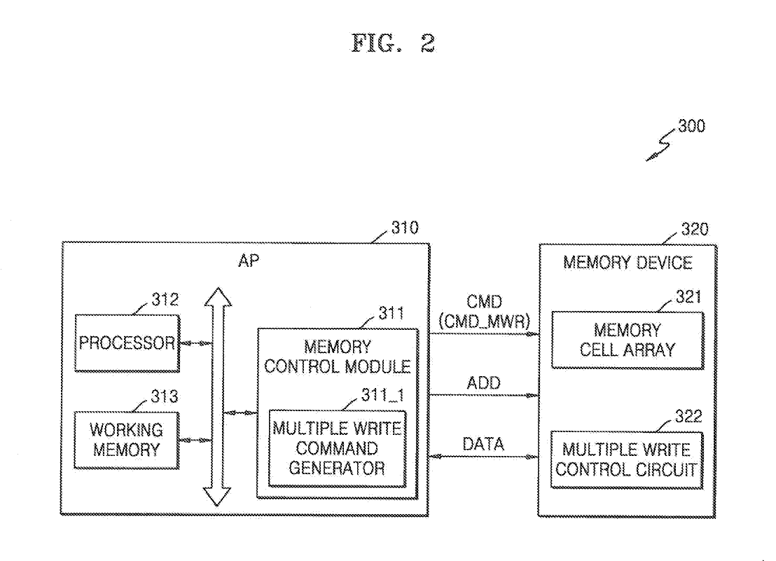

FIG. 2 is a block diagram illustrating another example of a memory system 300 according to an example embodiment of the inventive concepts. In FIG. 2, the memory system 300 that includes an application processor 310 and a memory device 320 is illustrated. A memory control module 311 of the application processor 310 may configure and/or control the memory device 320. For example, the memory control module 311 may provide a command CMD, an address ADD, and/or data DATA to the memory device 320. Also, the memory control module 311 may include a multiple write command generator 311_1. The memory device 320 may include a memory cell array 321 and a multiple write control circuit 322. According to the above-described embodiment, the multiple write control circuit 322 may perform a control operation of writing the same data DATA in a plurality of banks of the memory cell array 321 together, in response to a multiple write command CMD_MWR from the memory control module 311.

The application processor 310 may perform a function of the host described above with reference to FIG. 1. Also, the application processor 310 may be implemented with a system on chip (SoC). The SoC may include a system bus to which a protocol having a certain bus standard is applied, and may include various intellectual properties (IPs) connected to the system bus. The bus standard of the system bus may use the advanced microcontroller bus architecture (AMBA) protocol of Advanced RISC Machine (ARM). A bus type of the AMBA protocol may include advanced high-performance bus (AHB), advanced peripheral bus (APB), Advanced Extensible Interface (AXI), AXI4, AXI coherency extensions (ACE), and/or the like. In addition, other types of protocols such as nNetwork of SONICs Inc., CoreConnect of IBM, open core protocol of OCP-IP, and/or the like may be applied to the system bus.

The memory control module 311 may perform a function of the memory controller according to the above-described embodiment. Also, the application processor 310 may further include a processor 312 and a working memory 313 which are connected to each other through the system bus. The processor 312 may control various operations of the application processor 310, and, for example, may control the memory control module 311 for accessing the memory device 320. Also, the processor 312 may control various operations in software according to execution of programs, and the working memory 313 may store the programs executed by the processor 312.

The multiple write operation according to the above-described embodiment may be performed based on determination by the memory control module 311. For example, regardless of control by the host (or the processor 312), the memory control module 311 may determine a need to perform the multiple write operation and may provide the multiple write command CMD_MWR to the memory device 320, based on a result of the determination. In some embodiments, the need to perform the multiple write operation may be determined by the host, and a multiple write request may be provided to the memory control module 311 according to control by the processor 312. The memory control module 311 may provide the multiple write command CMD_MWR to the memory device 320 in response to the multiple write request.

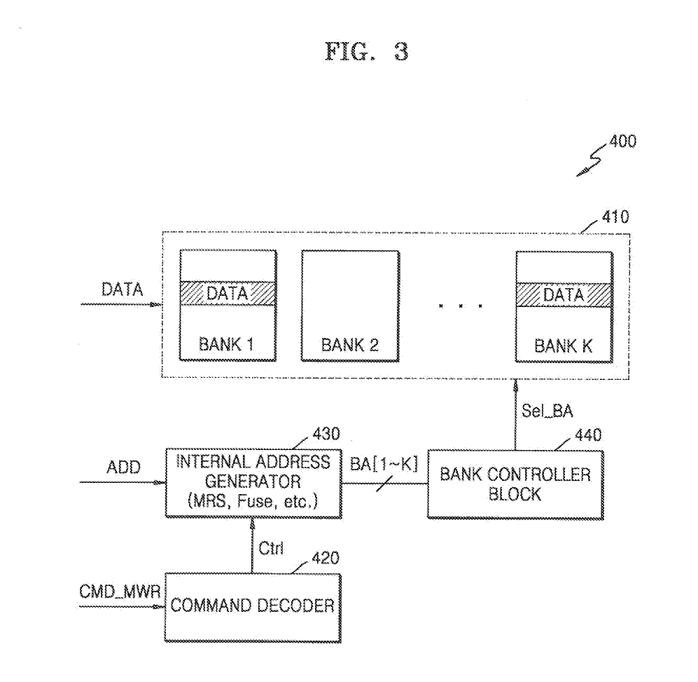

FIG. 3 is a block diagram of a memory device 400 illustrating an example of a multiple write operation.

Referring to FIG. 3, the memory device 400 may include a memory cell array 410 including a plurality of banks BANK 1 to BANK K, a command decoder 420, an internal address generator 430, and a bank controller block 440. At least one of the command decoder 420, the internal address generator 430, and the bank controller block 440 illustrated in FIG. 3 may perform operations associated with the multiple write control circuit (e.g., multiple write control circuit 220 of FIG. 1, multiple write control circuit 322 of FIG. 2) according to the above-described embodiments.

The command decoder 420 may decode a received command (e.g., received from the memory controller) and may control various elements of the memory device 400, based on a result of the decoding. For example, when a multiple write command CMD_MWR is received, the command decoder 420 may provide a control signal Ctrl for selecting two or more banks of the memory cell array 410 according to the decoding result. The internal address generator 430 may generate an internal address BA[1-K] for selecting banks on which a multiple write operation is to be performed, and for example, the internal address generator 430 may generate the internal address BA[1-K], based on the control signal Ctrl. In some embodiments, the selected banks indicated by the internal address BA[1-K] may be a subset of the total number of banks available in the memory cell array 410.

The internal address generator 430 may generate the internal address BA[1-K] representing banks on which multiple write is to be performed, based on various operations. For example, the internal address generator 430 may include a circuit which stores address information such as a mode register set MRS or a fuse array, and may generate the internal address BA[1-K] for selecting two or more banks, based on input information. FIG. 3 illustrates, for example, that the internal address generator 430 may generate the internal address BA[1-K] for selecting two or more banks based on an address ADD from a memory controller.

The bank controller block 440 may generate a bank selection signal Sel_BA in response to the internal address BA[1-K]. At least two of the banks BANK 1 to BANK K of the memory cell array 410 may be selected based on the bank selection signal Sel_BA, and data DATA from the memory controller may be together (e.g., simultaneously or non-simultaneously) written in two or more banks selected based on the bank selection signal Sel_BA. In FIG. 3, an example where the data DATA is together written in a first bank BANK 1 and a Kth bank BANK K is illustrated.

In an embodiment illustrated in FIG. 3, the internal address generator 430 may generate the internal address BA[1-K] by using the address ADD from the memory controller according to various operations. For example, the internal address generator 430 may select a bank indicated by the address ADD from the memory controller, and may further select at least one bank from among the other banks. In some embodiments, settings of the memory device 400 may indicate that two or more banks respectively correspond to values of the address ADD from the memory controller, and the internal address generator 430 may select two or more banks based on the address ADD regardless of a bank indicated by the memory controller.

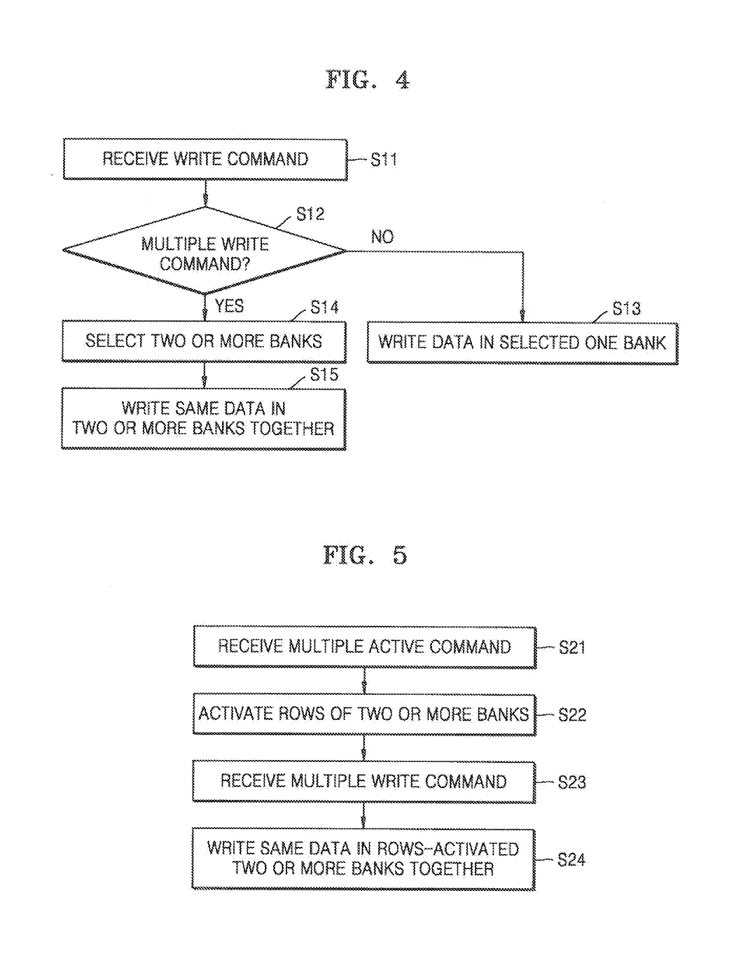

FIGS. 4 and 5 are flowcharts illustrating an operating method of a memory device according to example embodiments of the inventive concepts.

Referring to FIG. 4, the memory device (e.g., memory device 200, 320, 400) may receive various kinds of commands from a memory controller (e.g., memory controller 100, memory control module 311). For example, the memory device may receive a write command in operation S11. The memory device may decode the received write command to determine whether the write command corresponds to a multiple write command in operation S12.

If the received write command corresponds to a standard write command as a result of the determination, data received from the memory controller may be written in one bank. For example, the data may be written in one bank selected based on an address from the memory controller in operation S13.

If the received write command corresponds to a multiple write command, two or more banks may be selected through a multiple write control operation of the memory device in operation S14. For example, in some embodiments, two or more internal addresses may be generated by using an address from the memory controller, and two or more banks may be selected based on the internal addresses. In some embodiments, the address from the memory controller may include a plurality of bits, and by determining that one or more of the plurality of bits are don't care bits, two or more banks may be selected. A bit of data may be capable of representing a plurality (e.g., two) states. As used herein, a don't care bit is a bit of the data in which the individual state of the bit does not matter (e.g., is not taken into consideration or is interpreted as being capable of representing both states regardless of its actual value) when processing the data. When the banks are selected as described above, data may be together written in the selected two or more banks in operation S15.

Referring to FIG. 5, one or more rows of two or more banks may be activated for writing data together in the two or more banks. For example, the memory device may receive a multiple active command from the memory controller in operation S21, and may activate rows of the two or more banks in response to the multiple active command in operation S22. The multiple active command may be a command which is separately negotiated by the memory controller and the memory device, and an operation of selecting two or more banks, and/or banks which are to be activated by the same or similar manner, may be selected according to the multiple write command.

Subsequently, the memory device may receive the multiple write command according to the above-described embodiments in operation S23. Two or more banks may be selected by decoding the multiple write command, and for example, the memory controller may generate information (for example, field information) about the multiple write command so as to select the same banks as banks selected based on the multiple active command. The memory device may together write the same data in the activated rows of the two or more banks in response to the multiple write command in operation S24.

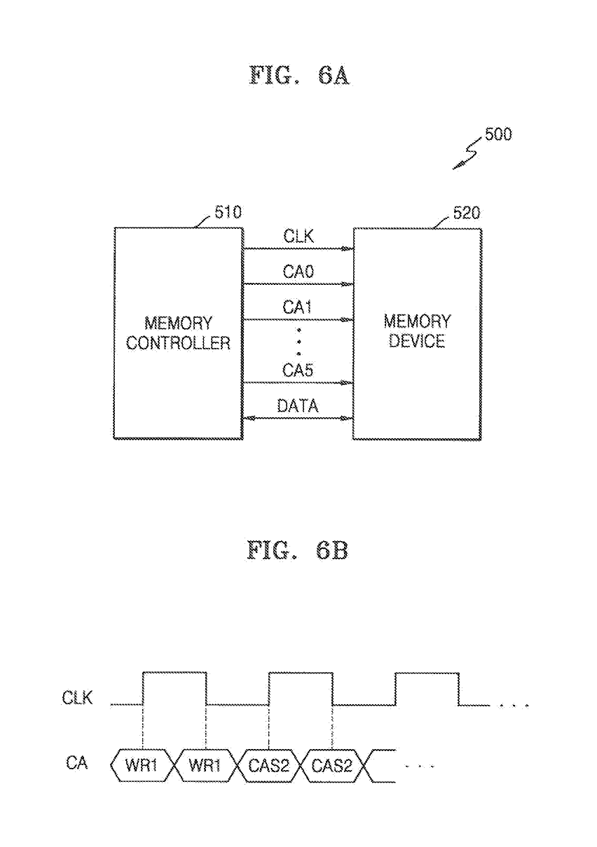

FIGS. 6A and 6B are block diagrams illustrating an example where an embodiment of the inventive concepts is applied to an LPDDR specification-based memory system or an HBM. For example, the memory system may perform communication based on the communication interface defined in the Joint Electron Device Engineering Council (JEDEC) Low Power Double Data Rate 4 (LPDDR4) specification, or other LPDDR specification.

Referring to FIGS. 6A and 6B, a memory system 500 may include a memory controller 510 and a memory device 520. The memory controller 510 and the memory device 520 may communicate with each other through a plurality of channels. For example, the memory system 500 may transmit a clock signal CLK to the memory device 520 and may transmit a command/address CA to the memory device 520 through a plurality of channels. For example, each of the memory controller 510 and the memory device 520 may transmit or receive a command/address signal CA[0:5] through six pins. The command/address signal CA[0:5] may correspond to six bits of the command/address CA. Also, data DATA may be transmitted or received between the memory controller 510 and the memory device 520. The command/address signal CA[0:5] may be transmitted to the memory device 520 in synchronization with a rising edge and/or a falling edge of the clock signal CLK. Hereinafter, in describing embodiments, a command (for example, a write command, a multiple write command, etc.) may be referred to in reference to a particular command/address signal CA[0:5]. It will be understood that a particular command/address CA may use more than six bits and thus may include a plurality of individually transmitted commands CA[0:5], as discussed herein.

The command/address signal CA[0:5] may include a command and an address according to the above-described embodiments. For example, when the memory controller 510 transmits a command for a data write operation to the memory device 520, the memory controller 510 may transmit a first write command WR1 in synchronization with a rising edge of the clock signal CLK, and then, may additionally transmit the first write command WR1 in synchronization with a falling edge of the clock signal CLK. Also, the memory controller 510 may transmit a second Column Access Strobe (CAS) command CAS2 in synchronization with a next rising edge of the clock signal CLK, and then, may additionally transmit the second CAS command CAS2 in synchronization with a next falling edge of the clock signal CLK. As illustrated in FIG. 6B, the two first write commands WR1 may be different from one another and may be portions of a write instruction (e.g., a first half and a second half of the write instruction) that are synchronized on the rising and falling edges of the clock signal CLK, respectively. Similarly, the two second CAS commands CAS2 may be different from one another and may be portions of a CAS instruction (e.g., a first half and a second half of the CAS instruction) that are synchronized on the rising and falling edges of the clock signal CLK, respectively. That is, the memory controller 510 may perform a command transmission operation requiring two clock cycles of the clock signal CLK in transmitting a write operation.

According to example embodiments of the inventive concepts, the multiple write command may have a combination of bits of the command/address signal CA[0:5]. For example, the multiple write command may be defined by one or more of four commands (two first write command WR1 and two second write command CAS2) shown in FIG. 6B. For example, the multiple write command may be defined by information about at least one (or at least some) of a plurality of fields (for example, fields CA0 to CA5) included in the first write command WR1 synchronized with a rising edge of the clock signal CLK. In some embodiments, the multiple write command may be defined by information about fields of at least one of the first write commands WR1 synchronized with a rising edge and/or a falling edge of the clock signal CLK. In addition, the multiple write command may be defined by further using information about fields of at least one of the second CAS commands CAS2 synchronized with a subsequent rising edge and/or falling edge of the clock signal CLK.

The number and positions of a plurality of banks in which data is to be written may be selected based on information included in a write command. For example, the number and positions of banks may be selected by using information about at least some fields included in the second CAS command CAS2 synchronized with a subsequent rising edge of the clock signal CLK. In some embodiments, the number and positions of banks may be selected by using information about fields included in at least one of the second CAS command CAS2 synchronized with a subsequent rising edge and/or falling edge of the clock signal CLK.

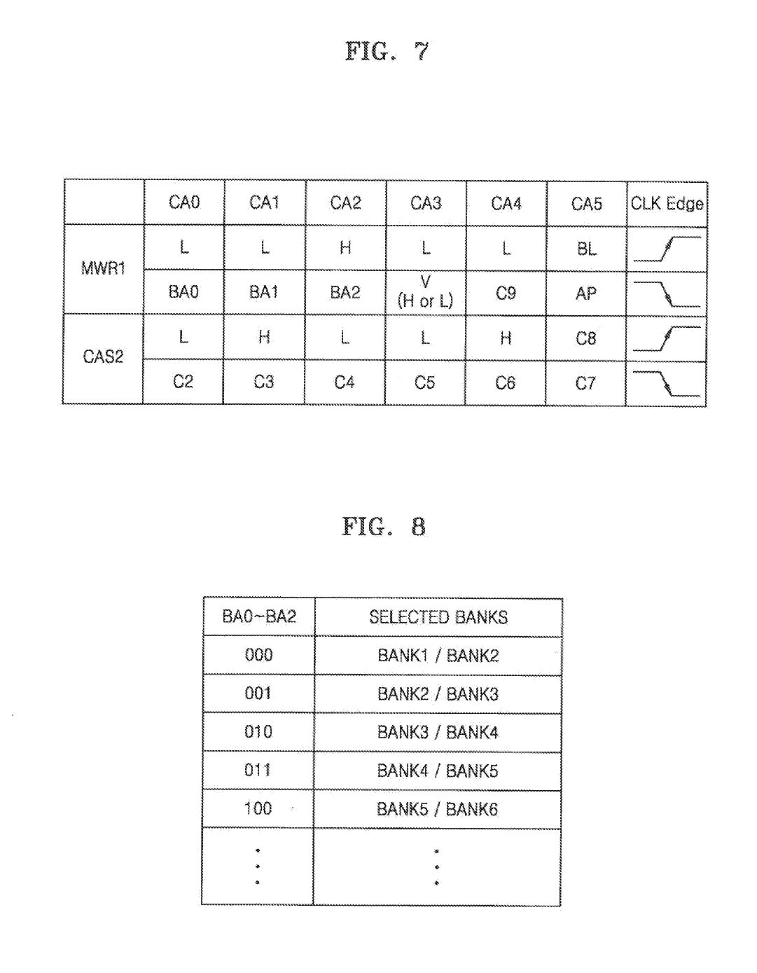

FIG. 7 is a table showing an implementation example of a command/address signal for defining a multiple write command.

Referring to FIG. 7, according to an embodiment of the inventive concepts, a multiple write command may be defined and may include pieces of information shown in FIG. 7. For example, the multiple write command may include four commands which are transmitted at respective rising and falling edges of two cycles of a clock signal CLK. For example, using a structure based on the LPDDR4 specification, the multiple write command may include first multiple write commands MWR1, which are transmitted in synchronization with a rising edge and a falling edge of the clock signal CLK, and second CAS write commands CAS2 which are transmitted in synchronization with a subsequent rising edge and falling edge of the clock signal CLK.

In FIG. 7, an example where the multiple write command defined by at least some pieces of information about fields of the first multiple write commands MWR1 transmitted in synchronization with a rising edge and a falling edge of the clock signal CLK is shown. For example, when a combination of first to fifth command/address signals CA[0:4] of a first multiple write command MWR1 transmitted in synchronization with a rising edge and one or more command/address signals of a first multiple write command MWR1 transmitted in synchronization with a falling edge has a certain pattern (or combination), a write command may be defined as corresponding to the multiple write command. According to an embodiment, one or more command/address signals, which are not used in a standard write command, of a first multiple write command MWR1 transmitted in synchronization with a falling edge may be used for defining the multiple write command, and in FIG. 7, an example where the fourth command/address signal CA3 is used for defining the multiple write command is shown.

As an implementation example, when a pattern of each of the first to fifth command/address signals CA[0:4] synchronized with a rising edge corresponds to “LLHLL” (where ‘L’ corresponds to a logic low and ‘H’ corresponds to a logic high) and the fourth command/address signals CA3 of a first multiple write command MWR1 synchronized with a falling edge corresponds to a first logic value (for example, logic high), the write command may be defined as corresponding to the multiple write command. On the other hand, when the pattern of each of the first to fifth command/address signals CA[0:4] corresponds to “LLHLL” and the fourth command/address signals CA3 of the first multiple write command MWR1 synchronized with the falling edge corresponds to a second logic value (for example, logic low), the write command may be defined as corresponding to the standard write command. In some embodiments, when the fourth command/address signals CA3 of the first multiple write command MWR1 synchronized with the falling edge corresponds to logic low, the write command may be defined as corresponding to the multiple write command.

Each of the commands may further include various pieces of different information associated with a memory operation. In an embodiment shown in FIG. 7, a sixth command/address signal CA5 of a first multiple write command MWRI synchronized with a rising edge of the clock signal CLK may represent a burst length BL associated with data write. Also, first to third command/address signals CA[0:2] of a first multiple write command MWRI synchronized with a falling edge of the clock signal CLK may represent bank addresses BA0 to BA2, the fifth command/address signals CA4 may represent a portion C9 of a column address, and the sixth command/address signals CA5 may correspond to a signal AP representing auto precharge. The first to fifth command/address signals CA[0:4] of a second CAS command CAS2 synchronized with a next rising edge of the clock signal CLK may correspond to information representing that a corresponding command is the second CAS command CAS2. The sixth command/address signal CA5 of the second CAS command CAS2 synchronized with a next rising edge of the clock signal CLK and first to sixth command/address signals CA[0:5] of the second CAS command CAS2 synchronized with a next falling edge of the clock signal CLK may represent column addresses C2 to C8.

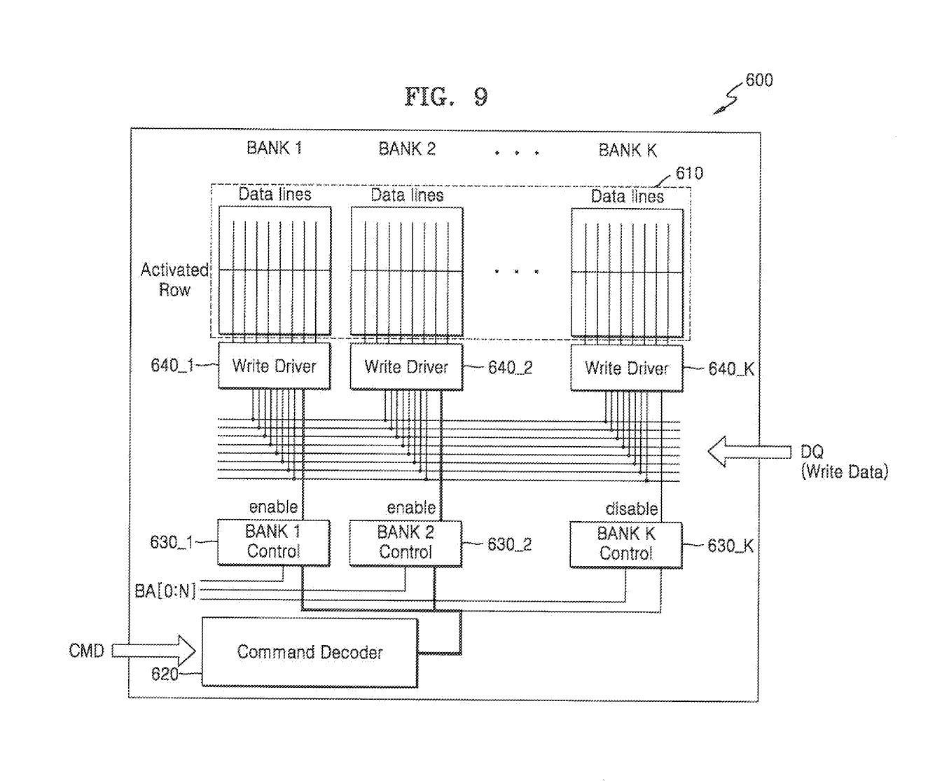

FIG. 8 is a table showing an example of selecting a plurality of banks on which multiple write is to be performed.

Referring to FIGS. 7 and 8, a bank selecting operation according to example embodiments may be variously performed. For example, the memory device may generate internal addresses for selecting two or more banks, based on bank addresses BA0 to BA2 provided from the memory controller (e.g., as part of the first multiple write command MWR1). For example, the memory device may include a circuit which stores internal addresses for selecting two or more banks, based on an input signal (for example, the bank addresses BA0 to BA2 provided from the memory controller), and for example, an element for generating an internal address through a storage circuit such as the mode register set or the fuse array may be implemented.

For example, when the bank addresses BA0 to BA2 correspond to “000,” internal addresses for selecting first and second banks BANK 1 and BANK 2 may be generated. For example, when the bank addresses BAO to BA2 correspond to “001,” internal addresses for selecting the second bank BANK 2 and a third bank BANK 3 may be generated. For example, when the bank addresses BAO to BA2 correspond to “100,” internal addresses for selecting a fifth bank BANK 5 and a sixth bank BANK 6 may be generated. The table shown in FIG. 7 is merely an implementation example, and according to an embodiment, internal addresses may be generated from the bank addresses BAO to BA2 in various configurations. Also, in FIG. 8, an example where data is together written in two banks is shown, but the inventive concepts are not limited thereto. For example, the number of banks in which data is together written based on a multiple write command may vary.

According to embodiments shown in FIGS. 7 and 8, a plurality of banks may be selected, and simultaneously, a position of a column in which data is to be written may be selected based on pieces of information included in the first multiple write commands MWRI and the second CAS commands CAS2. That is, in the embodiments of FIGS. 7 and 8, the same data may be written in a column corresponding to the same positions of different banks.

FIG. 9 is a block diagram illustrating an operation example where data is multiply written in a memory device 600 according to an embodiment of the inventive concepts.

Referring to FIG. 9, the memory device 600 may include a memory cell array 610 including a plurality of banks BANK 1 to BANK K, a command decoder 620, a bank controller block including a plurality of bank controllers 630_1 to 630_K, and a write driver block including a plurality of write drivers 640_1 to 640_K. Also, in FIG. 9, a data transfer path through which input/output data DQ is transferred is further illustrated, and the contents of the plurality of write drivers 640_1 to 640_K may be written in the plurality of banks BANK 1 to BANK K corresponding to write data received through the data transfer path.

The command decoder 620 may receive and decode a command CMD and may control various elements of the memory device 600 according to a result of the decoding. Also, each of the bank controllers 630_1 to 630_K may control an operation of selecting a corresponding bank, and for example, each of the bank controllers 630_1 to 630_K may receive a bank address BA[0:N] provided from a memory controller. For example, the bank address BA[0:N] may include a plurality of bits. In a standard write operation, one of the bank controllers 630_1 to 630_K may select a corresponding bank according to a bit value of the bank address BA[0:N], and the other bank controllers of the bank controllers 630_1 to 630_K may not select corresponding banks.

According to an embodiment, when the command decoder 620 receives a multiple write command, the command decoder 620 may provide a control signal for selecting two or more banks of the plurality of banks to the bank controllers 630_1 to 630_K. The control signal may include a signal for controlling a processing operation of each of the bank controllers 630_1 to 630_K. For example, the control signal may include a signal indicating that at least one bit of the bank address BA[0:N] provided to the bank controllers 630_1 to 630_K is a don't care bit.

As at least one bit of the bank address BA[0:N] is a don't care bit, at least two banks may be selected from among the plurality of banks BANK 1 to BANK K. FIG. 9 illustrates an example in which two banks are selected based on one bit of the bank address BA[0:N] being a don't care bit. For example, in FIG. 9, first and second banks BANK 1 and BANK 2 are selected by first and second bank controllers 630_1 and 630_2.

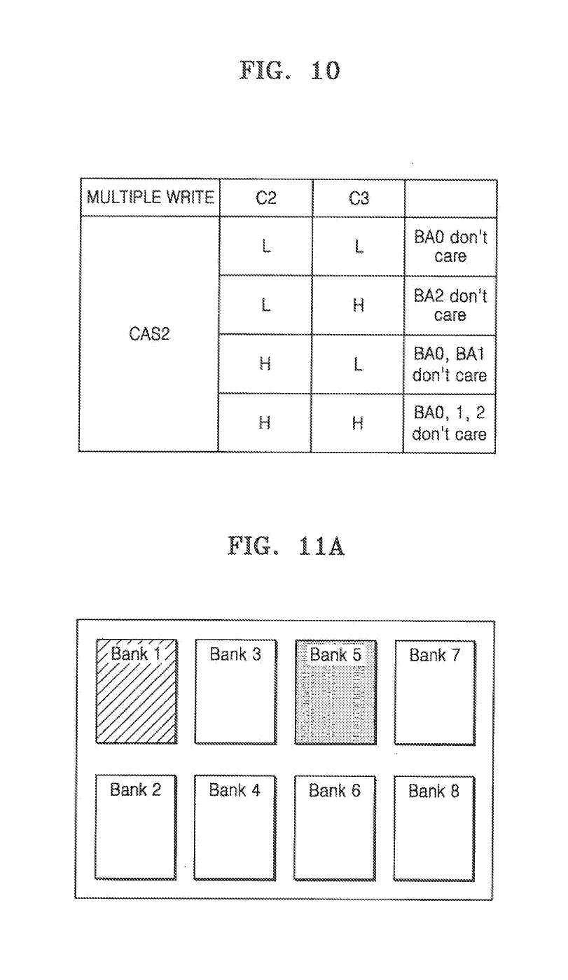

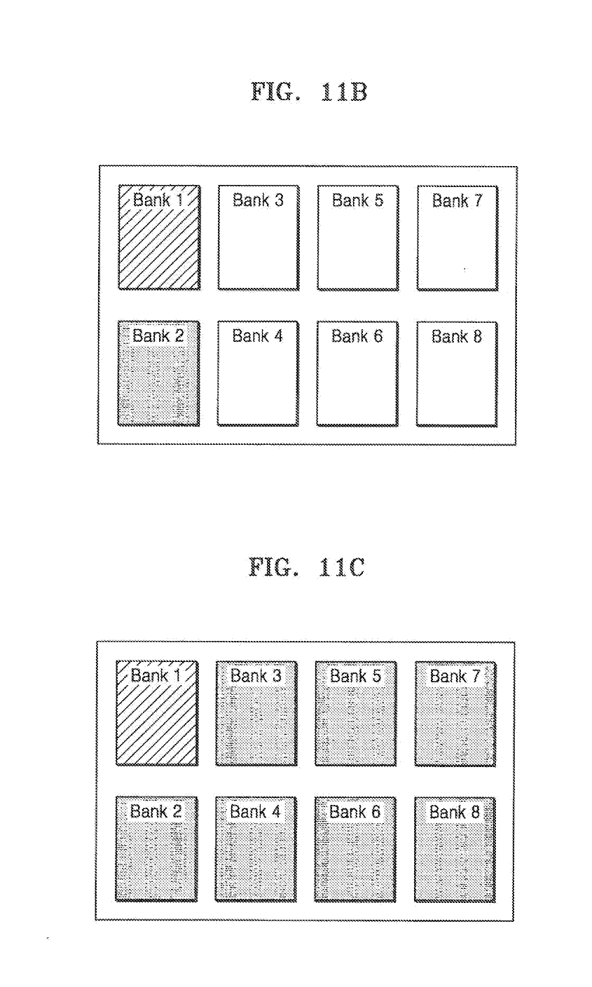

FIG. 10 is a table showing an example of don't care bits associated with at least one bit of a bank address, and FIGS. 11A, 11B, and 11C are block diagrams illustrating an example of a bank selecting operation based on the table of FIG. 10. In embodiments of FIGS. 10, 11A, 11B, and 11C, a bank address BA[0:N] is assumed as including three-bit bank addresses BA0 to BA2, though the inventive concepts are not limited thereto.

Referring to FIGS. 9, 10, 11A, 11B, and 11C, an operation of interpreting bank addresses BA0 to BA2 with at least one don't care bit may be controlled by a command CMD from a memory controller. For example, some various fields included in the command CMD may correspond to fields which are not used in a data write operation, and the interpretation of the bank addresses BA0 to BA2 with at least one don't care bit may be controlled by setting information about the unused one or more fields. In FIG. 10, in the above-described embodiment, an operation of interpreting the bank addresses BA0 to BA2 with at least one don't care bit by using pieces of information C2 and C3 from first and second command/address signals CA0 and CA1 of a second CAS command CAS2 synchronized with a falling edge of a clock signal is disclosed. In this example, the bank addresses BA0 to BA2 provided from the memory controller are assumed as corresponding to “L” (e.g., BA[0:2]=“LLL”). Also, a memory cell array is assumed as including eight banks BANK 1 to BANK 8, though the inventive concepts are not limited thereto.

When a decoding result of the command decoder 620 represents a multiple write operation, a bank selecting operation may be controlled by using the pieces of information C2 and C3 from the first and second command/address signals CA0 and CA1 of the second CAS command CAS2 synchronized with a falling edge of a clock signal (see FIG. 7). For example, when the pieces of information C2 and C3 represent “LL,” a first bank address BA0 of the bank addresses BAO to BA2 provided from the memory controller may be interpreted as a don't care bit. At this time, as illustrated in FIG. 11A, first and fifth banks BANK 1 and BANK 5 may be selected from among the eight banks BANK 1 to BANK 8. For example, the bank addresses BA[0:2] of “LLL” may be interpreted as “XLL,” where X indicates a don't care bit. This interpretation may match both “LLL” and “HLL,” which may indicate BANK 1 and BANK 5.

When the pieces of information C2 and C3 represent “LH,” a third bank address BA2 of the bank addresses BA0 to BA2 provided from the memory controller may be interpreted as a don't care bit. For example, the bank addresses BA[0:2] of “LLL” may be interpreted as “LLX,” where X indicates the don't care bit. This interpretation may match both “LLL” and “LLH” Thus, as illustrated in FIG. 11B, the first bank BANK 1 and a second bank BANK 2 may be selected from among the eight banks BANK 1 to BANK 8.

When the pieces of information C2 and C3 represent “HL,” first and second bank addresses BA0 and BAI of the bank addresses BA0 to BA2 provided from the memory controller may be interpreted as don't care bits. For example, the bank addresses BA[0:2] of “LLL” may be interpreted as “XXL,” where X indicates a don't care bit. This interpretation may match “LLL,” “LHL,” “HLL,” and “HHL.” As two bits of the three-bit bank addresses BA0 to BA2 are don't care bits, four of the eight banks BANK 1 to BANK 8 may be selected together.

When the pieces of information C2 and C3 represent “FM,” all of the bank addresses BA0 to BA2 provided from the memory controller may be interpreted as don't care bits. For example, the bank addresses BA[0:2] of “LLL” may be interpreted as “XXX,” where X indicates a don't care bit. As shown in FIG. 11C, all of the eight banks BANK 1 to BANK 8 may be selected, and thus, data may be written in the eight banks BANK 1 to BANK 8 together.

In the embodiments of FIGS. 11A to 11C, an obliquely-striped bank may be one bank indicated by an address from the memory controller, and a dotted bank may be one or more banks additionally selected by an internal address of the memory device based on the interpretation of the don't care bits.

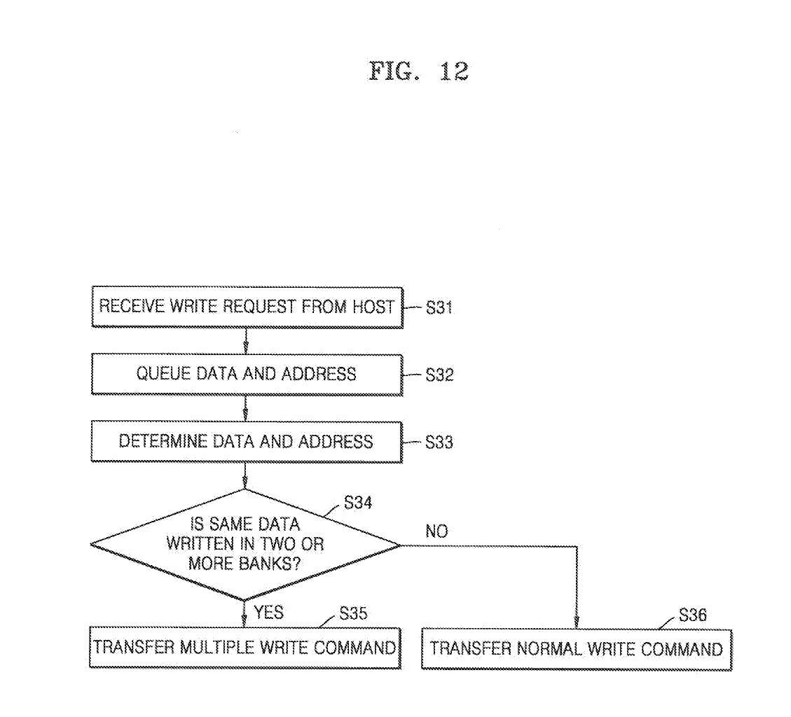

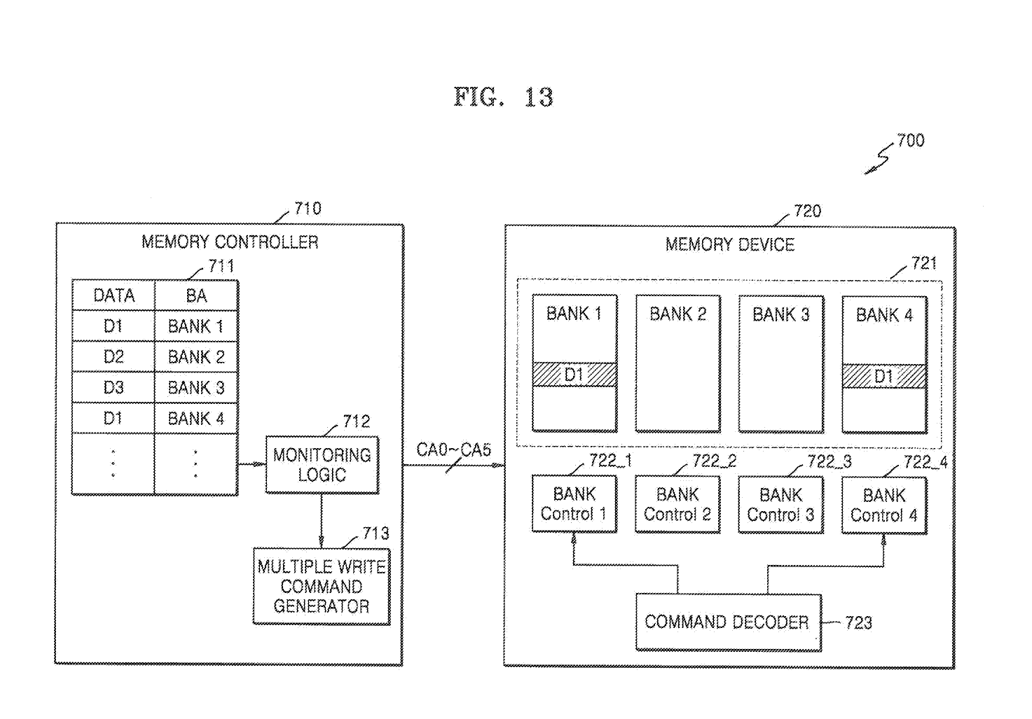

FIGS. 12 and 13 are diagrams illustrating an implementation example and an operating method of a memory system according to embodiments of the inventive concepts.

Referring to FIGS. 12 and 13, the memory system 700 may include a memory controller 710 and a memory device 720, and the memory controller 710 may access data of the memory device 720 according to a request from a host. For example, the memory controller 710 may receive a data write request from the host in operation 531, and may receive data and an address corresponding to the request.

The memory controller 710 may include a queue 711 which stores data of the memory controller 710 and an address corresponding thereto, and may queue the data and the address according to a write request from the host in operation S32. As a plurality of write requests are received from the host, pieces of data and addresses corresponding thereto may be stored in the memory controller 710. Also, the stored addresses may include addresses (for example, bank addresses) representing a position of a bank in which data is to be written.

The memory controller 710 may determine data and an address stored therein in operation S33. For example, the memory controller 710 may determine whether the same data is queued in plurality, and moreover, may determine whether the same data is written in banks corresponding to different positions in operation S34.

As a result of the determination, some pieces of data (for example, first data) may correspond to data written in two or more banks, and the memory controller 710 may generate a multiple write command for writing the first data and may transfer the multiple write command in operation S35. The memory device 720 may decode a multiple write command, and according to the above-described embodiments, the first data may be written in two or more banks together. On the other hand, some other pieces of data (for example, second data) may correspond to data written in one bank indicated by the host, and the memory controller 710 may generate a standard write command for writing the second data and may transfer the standard write command in operation S36. The memory device 720 may decode the standard write command and may write the second data in a bank indicated by an address from the memory controller 710.

According to the above-described embodiment, a multiple write operation may be performed based on determination by the memory controller 710 (or the memory system 700) irrespective of a request from the host. Also, since the first data is to be written in a bank corresponding to a position requested by the host, the memory controller 710 may provide bank addresses, representing positions of two or more banks provided from the host, to the memory device. In some embodiments, information including various selection combinations of banks may be stored in the memory device 720, and the memory device 720 may together write the first data in a plurality of banks, based on generation of an internal address from an address provided from the memory controller 710.

FIG. 13 illustrates a detailed example of an operation according to the embodiment of FIG. 12.

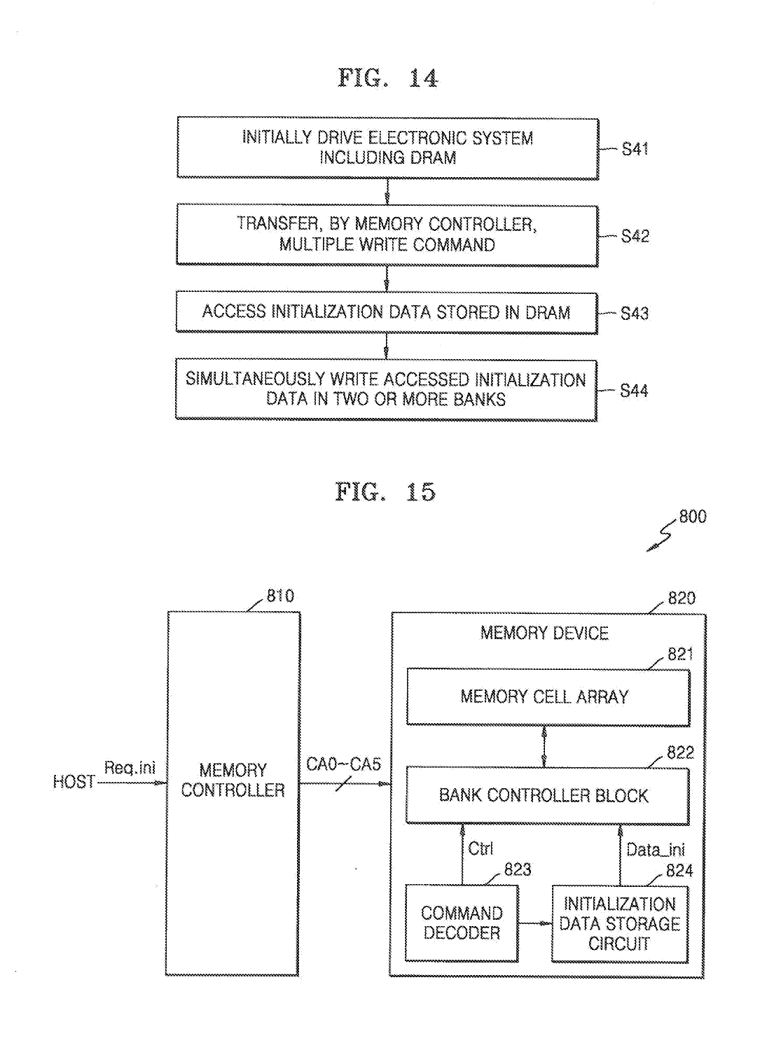

Referring to FIG. 13, a memory system 700 may include a memory controller 710 and a memory device 720, and the memory controller 710 may include a data/address queue 711, a monitoring logic 712, and a multiple write command generator 713. Also, the memory device 720 may include a memory cell array 721 including a plurality of banks, a plurality of bank controllers 722_1 to 722_4, and a command decoder 723. In the embodiment of FIG. 13, four banks BANK 1 to BANK 4 and four bank controllers 722_1 to 722_4 corresponding thereto are illustrated. The example of FIG. 14 illustrates an embodiment in which the memory controller 710 provides a command including command/address signals CAO to CA5 to the memory controller 710 in a signal configuration similar to the LPDDR specification.

Various pieces of data DATA may be queued in the data/address queue 711, and moreover, corresponding bank addresses BA may be queued in the data/address queue 711. For example, first data D1 may be written in first and fourth banks BANK 1 and BANK 4, second data D2 may be written in a second bank BANK 2, and third data D3 may be written in a third bank BANK 3. The monitoring logic 712 may monitor pieces of data DATA and bank addresses BA queued in the data/address queue 711 and may determine whether the same data is written in banks corresponding to different positions, based on a result of the monitoring. The monitoring logic 712 may provide a determination result to the multiple write command generator 713, and for example, may provide information representing a plurality of banks (for example, the first and fourth banks BANK 1 and BANK 4) in which the first data DI is to be written.

The multiple write command generator 713 may generate a multiple write command to control a write of the first data D1 in the first and fourth banks BANK 1 and BANK 4 and may transfer the multiple write command to the memory device 720. According to the above-described embodiment, the multiple write command may include a plurality of commands (e.g., synchronized with one or more rising and/or falling edges of a clock signal), and the commands may respectively include command/address signals CA0 to CA5. The command/address signals CA0 to CA5 may have a certain pattern which defines the multiple write command, and bank address information may be included in the command/address signals CA0 to CA5. The multiple write command generator 713 may set information about a bank address in order for the first and fourth banks BANK 1 and BANK 4 to be selected in the memory device 720 and may transfer the information to the memory device 720.

The command decoder 723 may decode the command/address signals CA0 to CA5 and may control the bank controllers 722_1 to 722_4, based on a result of the decoding. For example, first and fourth bank controllers 722_1 and 722_4 may select the first and fourth banks BANK 1 and BANK 4, based on control by the command decoder 723, and the first data D1 may be written in the first and fourth banks BANK 1 and BANK 4 together.

FIGS. 14 and 15 are diagrams illustrating an implementation example and an operating method of a memory device according to other embodiments of the inventive concepts. Hereinafter, an example of an operation in initial driving of an electronic system 800 to which a memory controller 810 and a memory device 820 (for example, DRAM) are applied will be described with reference to FIGS. 14 and 15.

Referring to FIGS. 14 and 15, an electronic system 800 to which DRAM is applied as a memory device 820 may be initially driven in operation S41, and initialization data may be written in a plurality of banks included in the DRAM 820 during the initial driving. Whenever the electronic system to which the DRAM 820 is applied is initially driven, initialization data having the same value may be written in the plurality of banks, and the initialization data may have a certain data pattern. In some embodiments, as data having a value “0” or “1” is written in all of the plurality of banks, an initialization operation may be performed. For example, when the initialization data is set in the DRAM 820, data having the same pattern may be stored in the plurality of banks.

As the electronic system is initially driven, a memory controller 810 may perform an initialization data write operation, based on a multiple write operation according to embodiments of the inventive concepts described herein. For example, the memory controller 810 may transfer a multiple write command to the DRAM 820 in operation 542. Also, the memory controller 810 may add information for indicating the number and positions of a plurality of banks, in which the initialization data is to be written, to the multiple write command. According to the above-described embodiments, the number and positions of the plurality of banks may be selected by setting various pieces of information included in a command.

According to an embodiment, the initialization data may have a certain pattern and may be stored in the memory controller 810 or the DRAM 820. For example, when the initialization data is stored in the memory controller 810, the memory controller 810 may transfer the multiple write command and the initialization data corresponding thereto to the DRAM 820. On the other hand, as illustrated in FIG. 14, when the initialization data is stored in the DRAM 820, the memory controller 810 may transfer only the multiple write command to the DRAM 820, and the DRAM 820 may access the initialization data stored therein in operation S43. Also, the DRAM 820 may write the accessed initialization data in two or more banks (e.g., simultaneously or non-simultaneously) in response to the multiple write command in operation S44.

According to the embodiment of FIG. 14, the memory controller 810 may determine an initialization operation and may perform a multiple write operation, based on a result of the determination. For example, the memory controller 810 may determine the initialization operation according to information from a host and may perform the multiple write operation, based on a result of the determination. In some embodiments, in the initialization operation, the host may issue a request, to the memory controller 810, to write the initialization data based on a multiple write operation, and the memory controller 810 may perform the multiple write operation, based on a request from the host.

FIG. 15 is a detailed operation example according to the embodiment of FIG. 14.

Referring to FIG. 15, a memory system 800 may include a memory controller 810 and a memory device 820, and the memory device 820 may include a memory cell array 821 including a plurality of banks, a bank controller block 822, a command decoder 823, and an initialization data storage circuit 824. Detailed descriptions of the same elements as the above-described embodiments among the elements illustrated in FIG. 15 are omitted.

The memory controller 810 may receive an initialization request Req_ini from a host HOST. The memory controller 810 may output command/address signals CA0 to CA5, having a combination corresponding to a multiple write command to the memory device 820 so as to perform initialization of the memory system 800, based on the above-described multiple write operation. The command decoder 823 may provide a control signal Ctrl for selecting two or more banks to the bank controller block 822 in response to the multiple write command.

The initialization data storage circuit 824 may store initialization data Data_ini having a certain data pattern and may provide the initialization data Data_ini to the memory cell array 821 through the bank controller block 822, based on control by the command decoder 823. The initialization data Data_ini may be written in two or more banks (e.g., simultaneously or non-simultaneously) that are selected based on the control signal Ctrl.

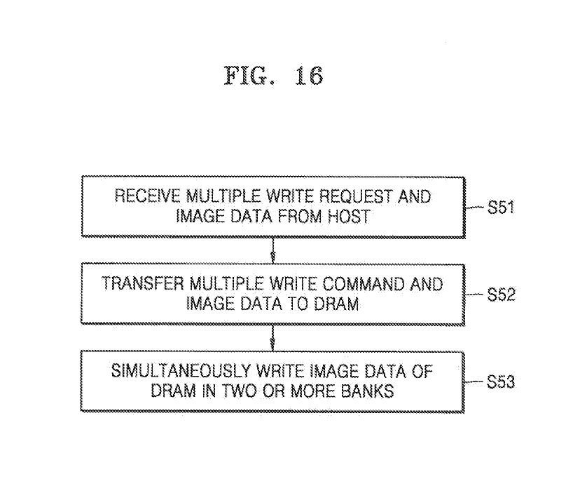

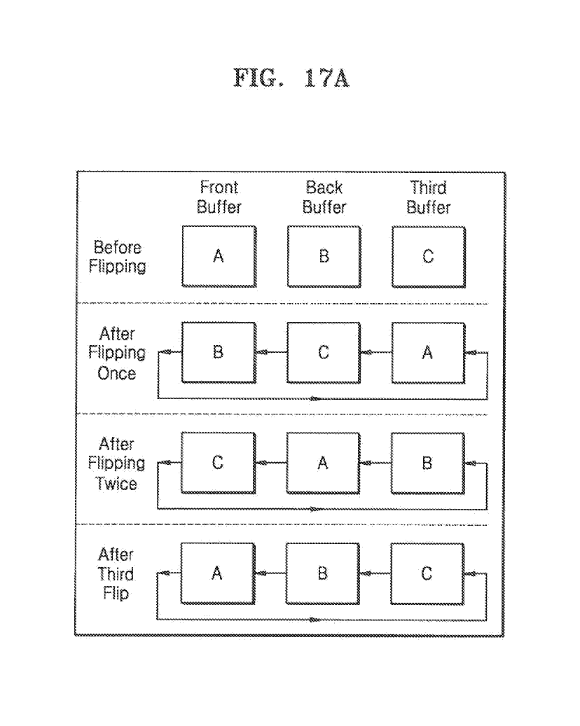

FIG. 16 is a diagram illustrating an implementation example and an operating method of a memory system according to other embodiments of the inventive concepts. In FIG. 16, an example where an electronic system (or a host) generates a multiple write request under a certain condition of the electronic system to which a memory system including a memory controller and a memory device (for example, DRAM) is applied is illustrated.

The electronic system may provide the multiple write request to the memory controller under various conditions. For example, the DRAM of the memory system may store image data for displaying a screen in the electronic system, and the electronic system may provide a request so that image data for displaying a predetermined screen (for example, a blue screen or the like) is written in the DRAM through a multiple write operation according to the above-described embodiments. The predetermined screen may include repetitive image data repeated at multiple locations within the predetermined screen.

Referring to FIG. 16, the electronic system may determine a certain condition and may transfer a multiple write request for together (e.g., simultaneously or non-simultaneously) writing the same data in a plurality banks of the DRAM. The memory controller may receive the multiple write request and data (for example, image data) from the host in operation S51. In response to the multiple write request from the host, the memory controller may transfer the image data and a multiple write command for writing the image data to the DRAM in operation S52. Also, the DRAM may receive the multiple write command and may together (e.g., simultaneously or non-simultaneously) write the image data in the plurality of banks in operation S53.

In some embodiments, a multiple write operation may be performed on data according to a request of the host. The host may reduce the frequency of repetitively providing the same data to the memory controller, and thus, bus capacity between the host and the memory controller may be efficiently used, and a time taken in writing image data in the DRAM may be shortened.

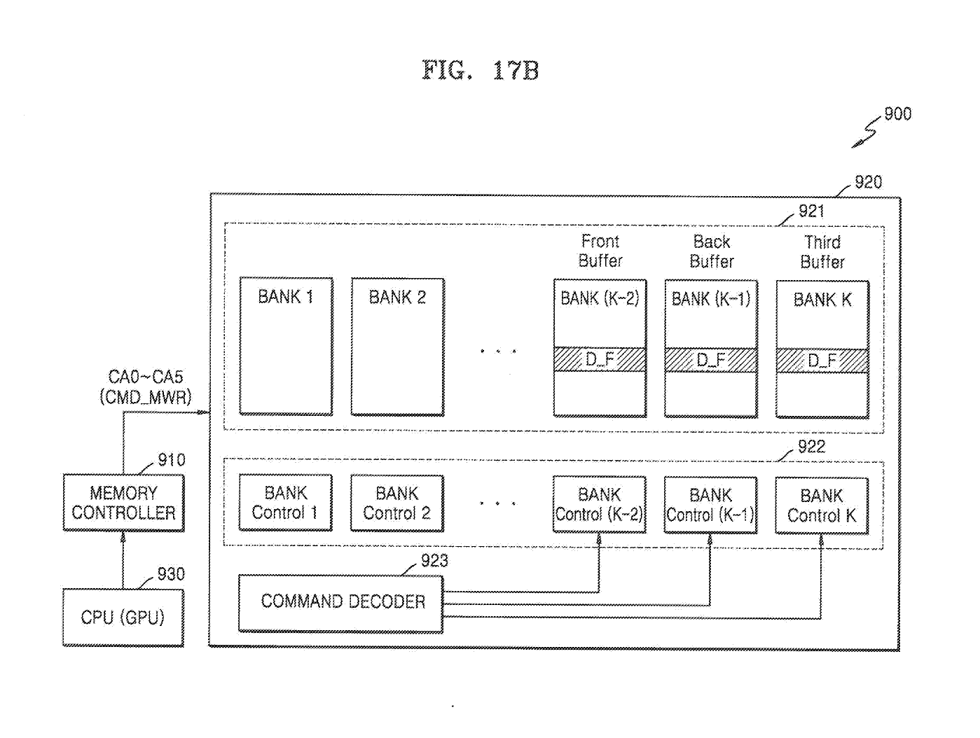

FIGS. 17A and I7B are diagrams illustrating an implementation example and an operating method of a memory device according to other embodiments of the inventive concepts. In FIGS. 17A and 17B, a triple buffer structure for storing image data for displaying a screen is illustrated, and an example where a memory device includes a plurality of frame buffers (for example, three frame buffers) is illustrated.

Referring to FIG. 17A, the memory device may include three frame buffers, and the three frame buffers may include a front buffer, a back buffer, and a third buffer. The front buffer may be a frame buffer for displaying a current scene, the back buffer may be a frame buffer for displaying a next scene, and the third buffer may be a frame buffer for displaying a scene subsequent to the next scene. When an output operation of the front buffer is completed, image data stored in the back buffer may move to the front buffer, and image data stored in the third buffer may move to the back buffer, based on a flipping operation.

As a frame rate increases, a probability that the same data is written in a background region of a screen increases progressively, and thus, a possibility that the same data is written in the three frame buffers increases. In this case, according to embodiments, the same data may be together written in a plurality of banks configuring the three buffers, based on a multiple write operation.

Referring to FIG. 17B, an electronic system 900 may include a memory controller 910, a memory device 920, and a processing unit 930. The processing unit 930 may correspond to various kinds of processing units such as a central processing unit (CPU), a graphic processing unit (GPU), etc.

The memory device 920 may include a memory cell array 921 including a plurality of banks BANK 1 to BANK K, a bank controller block 922 including a plurality of bank controllers corresponding thereto, and a command decoder 923. Also, K-2nd to Kth banks, BANK (K-2), BANK (K-1), and BANK K, of the plurality of banks BANK 1 to BANK K may configure the above-described three frame buffers. The memory controller 910 may provide various kinds of commands, and according to the above-described embodiments, may provide a multiple write command CMD_MWR to the memory device 920. Also, according to an embodiment, the memory controller 910 may provide the memory device 920 with command/address signals CA0 to CA5 based on the LPDDR specification as a command.

The processing unit 930 may function as a host, and the memory controller 910 may write image data in the K-2nd to Kth banks, BANK (K-2) to BANK K, according to a request from the processing unit 930. For example, in a write operation on the K-2nd to Kth banks, BANK (K-2) to BANK K, the memory controller 910 may control the memory device 920 to write data, based on a multiple write operation according to the above-described embodiments. For example, the memory controller 910 may provide the memory device 920 with the multiple write command CMD_MWR which allows image data to be together (e.g., simultaneously or non-simultaneously) written in the K-2nd to Kth banks, BANK (K-2) to BANK K.

In the present embodiment, a multiple write operation may be performed based on a request from the processing unit 930. In some embodiments, the memory controller 910 may receive a data access request from various kinds of processing units, and when a data write request is provided by a GPU which is dedicatedly used for image processing, the memory controller 910 may provide the memory device 920 with the multiple write command CMD_MWR according to the above-described embodiments.

In the memory device for performing multiple write operation, the operating method of the memory device, and the operating method of the memory controller according to the embodiments of the inventive concepts described herein, since the same data is simultaneously written in a plurality of regions of a memory cell array, a speed of the data write operation may be enhanced, an efficiency of the use of a bus may increase, and the reliability of data may be enhanced.

Moreover, in the memory device for performing a multiple write operation, the operating method of the memory device, and the operating method of the memory controller according to the embodiments of the inventive concepts described herein, a time taken in an initialization operation of the memory system may be reduced.

It will be understood that although the terms “first,” “second,” etc. are used herein to describe members, regions, layers, portions, sections, components, and/or elements in example embodiments of the inventive concepts, the members, regions, layers, portions, sections, components, and/or elements should not be limited by these terms. These terms are only used to distinguish one member, region, portion, section, component, or element from another member, region, portion, section, component, or element. Thus, a first member, region, portion, section, component, or element described below may also be referred to as a second member, region, portion, section, component, or element without departing from the scope of the inventive concepts. For example, a first element may also be referred to as a second element, and similarly, a second element may also be referred to as a first element, without departing from the scope of the inventive concepts.

The terminology used herein is for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by those of ordinary skill in the art to which the inventive concepts pertain. It will also be understood that terms, such as those defined in commonly used dictionaries, should be interpreted as having a meaning that is consistent with their meaning in the context of this specification and the relevant art and will not be interpreted in an idealized or overly formal sense unless expressly so defined herein.

When a certain example embodiment may be implemented differently, a specific process order may be performed differently from the described order. For example, two consecutively described processes may be performed substantially at the same time or performed in an order opposite to the described order.

As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”).

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

While the inventive concepts have been particularly shown and described with reference to embodiments thereof, it will be understood that various changes in form and details may be made therein without departing from the spirit and scope of the following claims.

1. An operating method of a memory device including a plurality of banks, the operating method comprising:
receiving a write command, and data and an address corresponding to the write command;
decoding the write command; and
responsive to a result of the decoding indicating that the write command corresponds to a multiple write command, together writing the same data in two or more banks using an internal address generating operation that is based on the received address.

2. The operating method of claim 1, further comprising, responsive to the result of the decoding indicating that the write command corresponds to a standard write command, writing the data in one bank indicated by the received address.

3. The operating method of claim 1, wherein the memory device communicates the write command with a memory controller using command/address signals including fields CA0, CA1, CA2, CA3, CA4, and CA5 based on a low power double data rate (LPDDR) communication interface.

4. The operating method of claim 3, wherein the write command comprises a first portion of a first write command synchronized with a rising edge of a clock signal and a second portion of the first write command synchronized with a falling edge of the clock signal, and
wherein the multiple write command is determined by decoding information about at least one of the fields CA0, CA1, CA2, CA3, CA4, and CA5 of the first portion of the first write command synchronized with the rising edge of the clock signal.

5. The operating method of claim 4, wherein the multiple write command is determined by further decoding information about at least one of the fields CA0, CA1, CA2, CA3, CA4, and CA5 of the second portion of the first write command synchronized with the falling edge of the clock signal.

6. The operating method of claim 5, wherein, responsive to the CA3 field of the second portion of the first write command synchronized with the falling edge of the clock signal having a first logic value, the write command is determined as the multiple write command, and
wherein, responsive to the CM field of the second portion of the first write command having a second logic value, the write command is determined as a command other than the multiple write command.

7. The operating method of claim 4, wherein the write command further comprises a second Column Access Strobe (CAS) command synchronized with a subsequent cycle of the clock signal after the first write command, and
wherein the two or more banks in which the same data is written are based on at least one of a plurality of fields included in the second CAS command.

8. The operating method of claim 1, wherein the memory device further comprises an address generator configured to store a plurality of internal addresses corresponding to the received address, and
wherein the operating method further comprises generating two or more internal addresses for selecting the two or more banks, based on a value of the received address.

9. The operating method of claim 1, wherein the two or more banks are selected based on at least one don't care bit of a bank address included in the received address.

10. The operating method of claim 9, wherein a location of the at least one don't care bit of the bank address is configured to vary based on at least one field of the write command.

11. The operating method of claim 1, wherein, in response to the multiple write command, the same data is written at a same column position of the two or more banks.

12. An operating method of a memory controller for controlling a memory device, the operating method comprising:
receiving an initialization request for the memory device from a host;
in response to the initialization request, generating a multiple write command to together write same initialization data in two or more banks of the memory device;
transferring the multiple write command to the memory device; and
transferring, to the memory device, a standard write command and an address indicating a position of a bank of the memory device in which data are to be written,
wherein the multiple write command and the standard write command transferred to the memory device respectively comprise a plurality of fields,
wherein a first combination of the plurality of fields of the multiple write command is different than a second combination of the plurality of fields of the standard write command.

13. The operating method of claim 12, wherein the initialization data is set in the memory device, and
wherein the multiple write command is transferred to the memory device without transferring the initialization data.

14. The operating method of claim 12, further comprising transferring a clock signal synchronized with the multiple write command,
wherein the write command comprises a first portion of a first write command synchronized with a rising edge of the clock signal and a second portion of the first write command synchronized with a falling edge of the clock signal.

15. The operating method of claim 14, wherein the memory controller communicates the first write command with the memory device using command/address signals including fields CA0, CA1, CA2, CA3, CA4, and CA5 based on a low power double data rate (LPDDR) communication interface, and
wherein an operation of the multiple write command is based on fields CA0, CA1, CA2, CA3, and CA4 of the first portion of the first write command synchronized with the rising edge of the clock signal and field CA3 of the second portion of the first write command synchronized with the falling edge of the clock signal.

16. The operating method of claim 14, wherein the multiple write command further comprises a second Column Access Strobe (CAS) command synchronized with a subsequent cycle of the clock signal after the first write command, and
wherein at least one field of the second CAS command comprises information about the two or more banks of the memory device in which the same initialization data is together written.

17. The operating method of claim 12, further comprising:
receiving a plurality of data and a plurality of addresses according to one or more write requests from the host;
checking the received plurality of data and the received plurality of addresses to determine whether a same data is requested to be written in the two or more banks of the memory device;
transferring the multiple write command to the memory device, based on a result of the determination; and
transferring bank addresses, indicating the two or more banks corresponding to the multiple write command, to the memory device according to the received plurality of addresses.

18. (canceled)

19. A memory device comprising:
a memory cell array including a plurality of banks;
a command decoder configured to decode a write command and an address received from a memory controller to control a write operation on the plurality of banks; and
a bank controller block configured to select one or more of the plurality of banks in which data is to be written,
wherein, responsive to the command decoder decoding the write command as a standard write command, the data is written in one bank of the plurality of banks indicated by the address received from the memory controller, and
wherein, responsive to the command decoder decoding the write command as a multiple write command, the data is together written in two or more banks of the plurality of banks of the memory cell array through an internal bank selecting operation.

20. The memory device of claim 19, further comprising an internal address generator configured to generate an internal address for selecting the two or more banks, based on the address received from the memory controller.

21.-22. (canceled)

23. The memory device of claim 19, further comprising a storage circuit configured to store initialization data,
wherein, in an initialization operation of an electronic system including the memory device, the memory device receives the multiple write command from the memory controller, and
wherein, in response to the multiple write command, the initialization data is accessed from the storage circuit and is written simultaneously in the two or more banks of the plurality of banks of the memory cell array.

24. (canceled)
